(19) United States
(12) Patent Application Publication
(10) Pub. No.: US 2025/0149312 A1
(43) Pub. Date: May 8, 2025

(54) SUBSTRATE PROCESSING APPARATUS INCLUDING FLUID SUPPLY UNIT AND FLUID CONTROL METHOD FOR CONTROLLING FLOW VARIABILITY OF FLUID

(71) Applicant: SEMES CO., LTD., Cheonan-si (KR)

(72) Inventors: Tae Sung KIM, Cheonan-si (KR); Duk Hyun SON, Cheonan-si (KR)

(73) Assignee: SEMES CO., LTD., Cheonan-si (KR)

(21) Appl. No.: 18/939,452

(22) Filed: Nov. 6, 2024

(30) Foreign Application Priority Data
Nov. 8, 2023 (KR) 10-2023-0153582

(51) Int. Cl. H01J 37/32; G05D 7/06; H01L 21/683

(52) U.S. Cl. CPC H01J 37/32724; G05D 7/0623; H01L 21/6833

(57) ABSTRACT

Disclosed are a substrate processing apparatus including a fluid supply unit and a fluid control method for controlling a flow rate of fluid. The fluid control method for controlling a flow rate of fluid to be supplied to a lower surface of a substrate from a fluid supply unit including a fluid source for supplying fluid and fluid supply lines connected to the fluid source includes a dimension measurement step of measuring lengths and cross-sectional areas of the fluid supply lines, a volume calculation step of calculating volumes of the fluid supply lines using the lengths and the cross-sectional areas measured in the dimension measurement step, a time measurement step of opening a valve provided in the fluid source to measure a time for which fluid is supplied to the fluid supply lines, and a control step of controlling a flow rate of fluid based on data obtained in the previous steps.

### CROSS-REFERENCE TO RELATED APPLICATION(S)

This application claims priority under 35 U.S.C. § 119 to Korean Patent Application No. 10-2023-0153582, filed on Nov. 8, 2023 in the Korean Intellectual Property Office, the disclosure of which is incorporated by reference herein in its entirety.

### BACKGROUND OF THE INVENTION

### Field of the Invention

The present invention relates to a substrate processing apparatus including a fluid supply unit and a fluid control method for controlling flow variability (i.e., a flow rate) of fluid. More particularly, the present invention relates to a fluid supply unit that includes a plurality of fluid supply lines for supplying fluid to a lower surface of a substrate and is capable of minimizing flow variability of the fluid due to a pressure difference between the fluid supply lines.

### Description of the Related Art

In general, a process for manufacturing a semiconductor device includes a deposition process for forming a film on a semiconductor substrate, a chemical/mechanical polishing process for planarizing the film, a photoresist process for forming a photoresist pattern on the film, an etching process for forming a pattern having electrical characteristics on the film using the photoresist pattern, an ion implantation process for implanting specific ions into a predetermined region of the substrate, a cleaning process for removing impurities on the substrate, and an inspection process for inspecting the surface of the substrate on which the film or the pattern is formed.

Some of the above processes may use plasma. Plasma is generated under very high temperature, a strong electric field, or a radio frequency (RF) electromagnetic field. Plasma may be used in an etching, deposition, or cleaning process. During this plasma treatment process, fluid may be supplied to a lower surface of a substrate in order to maintain the temperature of the substrate at an appropriate level.

Generally, in a case of supplying fluid to a lower surface of a substrate, fluid supplied from one fluid supply unit branches into one or more fluid supply lines and then is supplied to the lower surface of the substrate. In this case, however, the amount of fluid flowing to the respective fluid supply lines is not uniform, which causes a temperature difference between regions included in one substrate. This adversely affects the substrate during a plasma treatment process, leading to defects in a semiconductor device.

### SUMMARY OF THE INVENTION

Therefore, the present invention has been made in view of the above problems, and it is an object of the present invention to provide a substrate processing apparatus including a fluid supply unit and a fluid control method for controlling flow variability of fluid to be supplied to a substrate in order to prevent the occurrence of a temperature difference between regions included in the substrate.

The objects to be accomplished by the invention are not limited to the above-mentioned object, and other objects not mentioned herein will be clearly understood by those skilled in the art from the following description.

In accordance with an aspect of the present invention, the above and other objects can be accomplished by the provision of a fluid control method for controlling a flow rate of fluid to be supplied to a lower surface of a substrate from a fluid supply unit including a fluid source configured to supply fluid and a plurality of fluid supply lines connected to the fluid source, the fluid control method including a dimension measurement step of measuring lengths and cross-sectional areas of the fluid supply lines, a volume calculation step of calculating volumes of the fluid supply lines using the measured lengths and the measured cross-sectional areas, a time measurement step of opening a valve provided in the fluid source to measure a time for which the fluid is supplied to the fluid supply lines, and a control step of controlling the flow rate of the fluid based on data on the lengths and the cross-sectional areas of the fluid supply lines, the volumes of the fluid supply lines, and the time.

In one embodiment, the lengths of the fluid supply lines may be lengths of the fluid supply lines provided at a substrate support unit configured to support the substrate, and the lengths may be measured using the valve provided in the fluid source as a reference point.

In one embodiment, the plurality of fluid supply lines may have the same cross-sectional area.

In one embodiment, the time may be a time period from a time point at which the valve provided in the fluid source is opened to a time point at which the fluid is completely supplied to the fluid supply lines.

In accordance with another aspect of the present invention, there is provided a fluid supply unit for supplying fluid to a lower surface of a substrate, the fluid supply unit including a fluid source configured to supply the fluid, a fluid supply line including one end connected to the fluid source and configured to supply the fluid, a pressure controller provided on the fluid supply line and configured to control pressure of the fluid, a flow rate controller provided on the fluid supply line and configured to control a flow rate of the fluid, and a fluid discharge line configured to discharge the supplied fluid. The fluid supply line includes a first fluid supply line configured to supply a portion of fluid branched from the fluid source and introduced thereinto to a first region corresponding to a center portion of a substrate support unit configured to support the substrate, a second fluid supply line configured to supply a portion of fluid branched from the fluid source and introduced thereinto to a second region defined around the first region, a third fluid supply line configured to supply a portion of fluid branched from the fluid source and introduced thereinto to a third region defined around the second region, and a fourth fluid supply line configured to supply the remaining portion of fluid branched from the fluid source and introduced thereinto to a fourth region defined around the third region.

In one embodiment, the fluid supply unit may further include a valve configured to open and close a passage configured to receive the fluid introduced thereinto from the fluid source.

In one embodiment, the pressure controller and the flow rate controller may be provided on each of the first to fourth fluid supply lines.

In one embodiment, each of the first to fourth fluid supply lines may include a valve.

In one embodiment, the flow rate controller may be an orifice.

In one embodiment, the fluid discharge line may be connected to a pump.

In one embodiment, each of the first to fourth fluid supply lines may be connected to the fluid discharge line.

In one embodiment, the fluid may be helium.

In accordance with a further aspect of the present invention, there is provided a substrate processing apparatus including a chamber including a processing space defined therein, a substrate support unit disposed in the processing space and configured to support a substrate, a gas supply unit configured to supply gas to the processing space, a plasma generation unit configured to convert the supplied gas into plasma, and a controller configured to control the gas supply unit and the plasma generation unit. The substrate support unit includes a fluid supply unit configured to supply fluid to a lower surface of the substrate. The fluid supply unit includes a fluid source configured to supply the fluid, a fluid supply line including one end connected to the fluid source and configured to supply the fluid, a pressure controller provided on the fluid supply line and configured to control pressure of the fluid, a flow rate controller provided on the fluid supply line and configured to control a flow rate of the fluid, and a fluid discharge line configured to discharge the supplied fluid. The fluid supply line includes a first fluid supply line configured to supply a portion of fluid branched from the fluid source and introduced thereinto to a first region corresponding to a center portion of the substrate support unit configured to support the substrate, a second fluid supply line configured to supply a portion of fluid branched from the fluid source and introduced thereinto to a second region defined around the first region, a third fluid supply line configured to supply a portion of fluid branched from the fluid source and introduced thereinto to a third region defined around the second region, and a fourth fluid supply line configured to supply the remaining portion of fluid branched from the fluid source and introduced thereinto to a fourth region defined around the third region.

In one embodiment, the substrate processing apparatus may further include a valve configured to open and close a passage configured to receive the fluid introduced thereinto from the fluid source.

In one embodiment, the pressure controller and the flow rate controller may be provided on each of the first to fourth fluid supply lines.

In one embodiment, each of the first to fourth fluid supply lines may include a valve.

In one embodiment, the fluid discharge line may be connected to a pump.

In one embodiment, each of the first to fourth fluid supply lines may be connected to the fluid discharge line.

In one embodiment, the first to fourth regions of the substrate support unit may have a concentric shape.

In one embodiment, the fluid may be helium.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a flowchart showing a fluid control method according to an embodiment of the present invention;

FIG. 2 is a diagram showing a result of simulating a fluid arrival time according to an embodiment of the present invention;

FIG. 3 is a view showing a substrate processing apparatus according to an embodiment of the present invention;

FIG. 4 is a view showing a substrate support unit according to an embodiment of the present invention;

FIG. 5 is a view showing a fluid supply unit according to an embodiment of the present invention; and

FIGS. 6 and 7 are views showing fluid supply units according to other embodiments of the present invention.

### DETAILED DESCRIPTION OF THE INVENTION

Hereinafter, embodiments of the present invention will be described in detail with reference to the accompanying drawings so that those skilled in the art can easily carry out the embodiments. The present invention may, however, be embodied in many different forms, and should not be construed as being limited to the embodiments set forth herein.

In the following description of the embodiments of the present invention, a detailed description of known functions or configurations incorporated herein will be omitted when it may unnecessarily obscure the subject matter of the present invention. Throughout the drawings, parts performing similar functions and operations are denoted by the same reference numerals.

At least some of the terms used in this specification are terms defined taking into consideration the functions obtained in accordance with the present invention, and may be changed in accordance with the intention of users or operators or usual practice. Therefore, the definitions of these terms should be determined based on the total content of this specification.

As used herein, singular forms may include plural forms, unless the context clearly indicates otherwise. Additionally, the term “comprise”, “include”, or “have” described herein should be interpreted not to exclude other elements but to further include such other elements unless mentioned otherwise.

In the drawings, the sizes or shapes of elements and thicknesses of lines may be exaggerated for clarity and convenience of description.

Hereinafter, embodiments of the present invention will be described in detail with reference to the accompanying drawings, and the same or similar elements are denoted by the same reference numerals even though they are depicted in different drawings, and redundant descriptions thereof will be omitted.

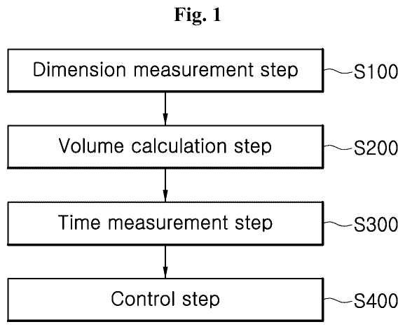

FIG. 1 is a flowchart showing a fluid control method according to an embodiment of the present invention.

Referring to FIG. 1, a method of controlling flow variability (i.e., a flow rate) of fluid to be supplied to a lower surface of a substrate from a fluid supply unit including a fluid source configured to supply fluid and a plurality of fluid supply lines connected to the fluid source may include a dimension measurement step S100 of measuring lengths and cross-sectional areas of the fluid supply lines, a volume calculation step S200 of calculating volumes of the fluid supply lines using the lengths and the cross-sectional areas measured in the dimension measurement step, a time measurement step S300 of opening a valve provided in the fluid source to measure a time for which the fluid is supplied to the fluid supply lines, and a control step S400 of controlling flow variability of the fluid based on data on the lengths and the cross-sectional areas of the fluid supply lines, the volumes of the fluid supply lines, and the time. In an embodiment, the flow variability may control the conductance of the fluid supplied to the lower surface of the substrate. Specifically, in the case where the temperature of the substrate is higher than a predetermined temperature, the flow variability of the fluid supplied to the lower surface of the substrate can be increased to lower a temperature of the substrate to the predetermined temperature. In the case where the temperature of the substrate is lower than the predetermined temperature, the flow variability of the fluid supplied to the lower surface of the substrate may be decreased to raise a temperature of the substrate to the predetermined temperature. Through this control of the flow variability, the temperature of the substrate in each area may be controlled more precisely.

The dimension measurement step S100 is a step of measuring lengths and cross-sectional areas of the fluid supply lines. The total lengths of the fluid supply lines provided at the substrate support unit may be measured using the valve provided in the fluid source as a reference point. In addition, the cross-sectional areas of the fluid supply lines may be measured. It is assumed that a fluid supply line according to an embodiment of the present invention diverges into a plurality of fluid supply lines and all of the plurality of fluid supply lines have the same cross-sectional area. According to an embodiment of the present invention, the substrate support unit may be divided into four regions in a concentric shape, and each of the fluid supply lines may be provided at a respective one of the four regions. Thus, the lengths of the fluid supply lines may vary depending on the regions. In an example, the fluid supply line provided at the center region among the four concentric regions has the shortest length, and the lengths of the fluid supply lines gradually increase in a direction approaching the outer periphery of the substrate support unit.

The volume calculation step S200 is a step of calculating volumes of the fluid supply lines using the lengths and the cross-sectional areas of the fluid supply lines measured in the dimension measurement step S100. The volumes of the fluid supply lines may be obtained by multiplying the lengths of the fluid supply lines by the cross-sectional areas of the fluid supply lines (lengths×cross-sectional areas). According to an embodiment of the present invention, since all of the fluid supply lines are assumed to have the same cross-sectional area, the volumes of the fluid supply lines may vary depending on the lengths thereof.

The time measurement step S300 is a step of measuring a time for which the fluid is supplied to the fluid supply lines.

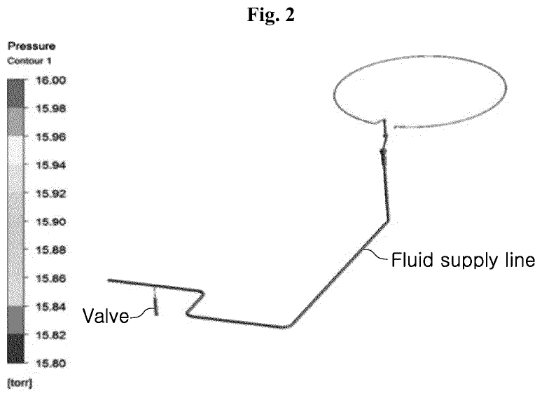

FIG. 2 shows a result of simulating a fluid arrival time according to an embodiment of the present invention.

Referring to FIG. 2, a time within which the fluid reached an electrostatic chuck was calculated using a conventional program, ANSYS® (ANSYS Inc., USA). Because it is impossible to directly know the time within which the fluid reached the electrostatic chuck, the time within which the fluid reached the electrostatic chuck may be calculated and estimated based on data measured in the dimension measurement step and the volume calculation step. In order to calculate the time within which the fluid reached the electrostatic chuck, the length of the fluid supply line was assumed to be 0.82 m, and the volume of the fluid supply line was assumed to be 16000 mm³, which was an average value of the volumes of the fluid supply lines calculated in the volume calculation step. As a result, the time within which the fluid reached the electrostatic chuck from the valve provided in the fluid source was 0.8 seconds. Based on this result, a time period from an actual valve opening time point at which the valve provided in the fluid source was opened to a time point at which the fluid was completely supplied to the interior of the fluid supply line was obtained. In this case, a determination as to whether the fluid is supplied to the interior of the fluid supply line may be made using a pressure controller provided on the fluid supply line. For example, if the fluid is not supplied to the interior of the fluid supply line, no pressure is measured by the pressure controller, and if the fluid is supplied to the interior of the fluid supply line, the pressure of the pressure controller changes. In this way, it is possible to determine whether the fluid is supplied to the interior of the fluid supply line. In an embodiment of the present invention, four fluid supply lines are provided, and the lengths thereof are different from one another. Therefore, it is preferable to obtain all of the fluid supply time periods of the respective fluid supply lines.

The control step S400 is a step of controlling flow variability of the fluid. The flow variability of the fluid may be controlled based on data on the lengths and the cross-sectional areas of the fluid supply lines measured in the dimension measurement step S100, the volumes of the fluid supply lines calculated in the volume calculation step S200, and the time measured in the time measurement step S300. In detail, it is possible to rapidly stabilize the flow rate of the fluid by maximizing the flow rate and the pressure of the fluid supplied to the substrate support unit in the initial stage and controlling the same based on the data measured in each of steps S100 to S300.

As described above, the flow variability of the fluid may be controlled by measuring and calculating data on the lengths, the cross-sectional areas, and the volumes of the fluid supply lines and the time. In addition, it is possible to stabilize the flow rate of the fluid supplied to the substrate support unit within about three seconds by increasing the flow rate and the pressure of the fluid supplied in the initial stage and controlling the same based on the above data.

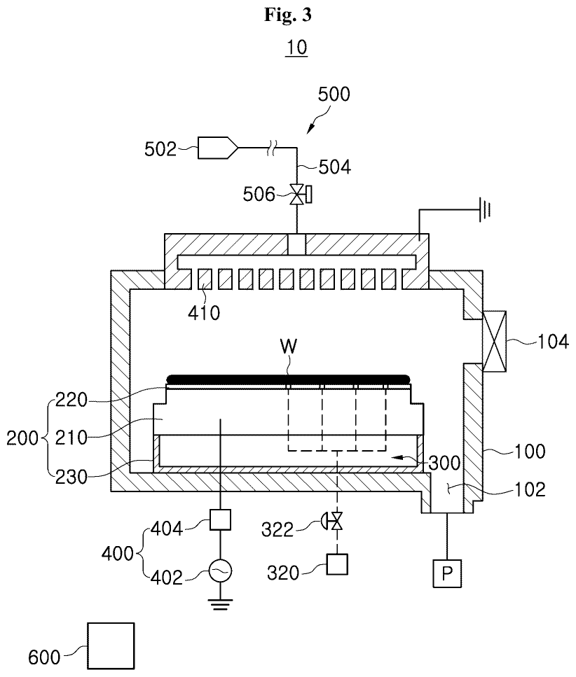

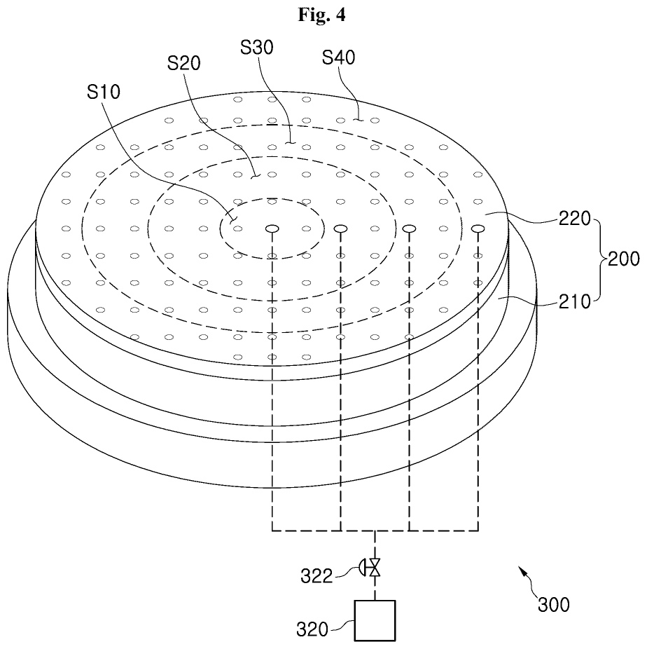

FIG. 3 is a view showing a substrate processing apparatus according to an embodiment of the present invention, and FIG. 4 is a view showing a substrate support unit according to an embodiment of the present invention.

Referring to FIG. 3, the substrate processing apparatus 10 according to the embodiment of the present invention may be an apparatus using plasma, and may include a chamber 100, a substrate support unit 200, a fluid supply unit 300, a plasma generation unit 400, a gas supply unit 500, and a controller 600.

The chamber 100 may have a processing space defined therein so as to allow a plasma process to be performed therein. The chamber 100 may include an exhaust port 102 formed in a lower side thereof, and the exhaust port 102 may be connected to an exhaust line on which a pump P is mounted. The exhaust port 102 may discharge reaction by-products generated during the plasma process and gas remaining in the chamber 100 to the outside of the chamber 100 through the exhaust line. In this case, pressure in the inner space in the chamber 100 may be reduced to a predetermined pressure.

The chamber 100 may include an opening 104 formed in the sidewall thereof. The opening 104 may function as a passage through which a substrate W enters the chamber 100. The opening 104 may be configured to be opened and closed by a door assembly.

The substrate support unit 200 may be disposed in a lower area in the chamber 100. The substrate support unit 200 may support the substrate W using electrostatic force. However, this embodiment is not limited thereto. The substrate W may be supported in various ways, such as mechanical clamping or vacuum support.

The substrate support unit 200 may include a support body 210 and an electrostatic chuck 220 disposed on the upper surface of the support body 210. The electrostatic chuck 220 may be configured to electrostatically attract and hold the substrate W, and may include a ceramic layer provided with an electrode.

Although not shown, the substrate support unit 200 may be provided therein with a heating member and a cooling member to maintain the substrate W at a process temperature. The heating member may be a heating coil, and the cooling member may be provided as a cooling line through which refrigerant flows.

A pedestal 230 may be provided under the support body 210 in order to support the support body 210 and the electrostatic chuck 220. The pedestal 230 may be formed in a cylindrical shape having a predetermined height, and may have a space defined therein. A lift pin assembly (not shown) may be provided in the pedestal 230.

Referring to FIG. 4, the substrate support unit 200 may be provided therein with a fluid supply unit 300 to supply the fluid to the lower surface of the substrate W. The substrate support unit 200 according to the embodiment of the present invention may be divided into four regions S10 to S40, and the four regions may have a concentric shape. The four regions S10 to S40 may include a first region, a second region S20, a third region S30, and a fourth region S40 divided around the center of the substrate support unit 200. Each of the fluid supply lines 340 of the fluid supply unit 300, which will be described in detail later, may be connected to a respective one of the four regions S10 to S40.

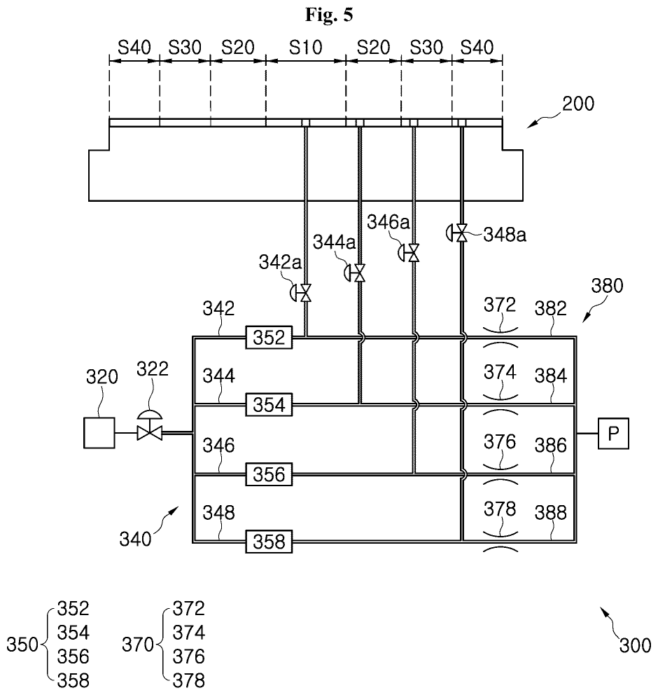

FIG. 5 is a view showing a fluid supply unit according to an embodiment of the present invention.

Referring to FIG. 5, the fluid supply unit 300 may include a fluid source 320, a fluid supply line 340, a pressure controller 350, a flow rate controller 370, and a fluid discharge line 380.

The fluid source 320 may supply fluid for control of the temperature of the substrate W to the fluid supply line 340. The fluid according to the embodiment of the present invention may be helium (He). However, the invention is not limited thereto. A valve 322 may be mounted on a passage interconnecting the fluid source 320 and the fluid supply line 340 in order to open and close the passage or to control the flow rate of the fluid flowing through the passage.

One end of the fluid supply line 340 may be connected to the fluid source 320, and the other end thereof may diverge into a plurality of fluid supply lines 342 to 348. In more detail, the fluid supply line 340 may diverge into a first fluid supply line 342, a second fluid supply line 344, a third fluid supply line 346, and a fourth fluid supply line 348. The plurality of branched fluid supply lines 342 to 348 may supply the fluid to the lower surface of the substrate W. According to an embodiment of the present invention, the first fluid supply line 342 may supply the fluid branched from the fluid source 320 and introduced thereinto to the first region S10 corresponding to the center portion of the substrate support unit 200. The second fluid supply line 344 may supply the fluid branched from the fluid source 320 and introduced thereinto to the second region S20 defined around the first region S10 of the substrate support unit 200. The third fluid supply line 346 may supply the fluid branched from the fluid source 320 and introduced thereinto to the third region S30 defined around the second region S20 of the substrate support unit 200. The fourth fluid supply line 348 may supply the fluid branched from the fluid source 320 and introduced thereinto to the fourth region S40 defined around the third region S30 of the substrate support unit 200. According to an embodiment of the present invention, valves 342a to 348a may be mounted on passages through which the fluid is supplied from the fluid supply lines 342 to 348 to the regions S10 to S40 of the substrate support unit 200 in order to open and close the passages or to control the flow rates of the fluid flowing through the passages.

The pressure controller 350 may be mounted on each of the plurality of fluid supply lines 342 to 348 in order to detect and control the pressure of the fluid flowing through a corresponding fluid supply line. The pressure controller 350 may include first to fourth pressure controllers 352 to 358 mounted on the first to fourth fluid supply lines 342 to 348, respectively. According to an embodiment of the present invention, it is preferable that the pressure of the fluid supplied to each of the first to fourth fluid supply lines 342 to 348 be 20 to 30 torr, and the plurality of pressure controllers 352 to 358 may be electronic pressure controllers (EPCs). However, the invention is not limited thereto.

In addition, the flow rate controller 370 may be mounted on each of the plurality of fluid supply lines 342 to 348 in order to detect and control the flow rate of the fluid flowing through a corresponding fluid supply line. The flow rate controller 370 according to the embodiment of the present invention may include first to fourth flow rate controllers 372 to 378. While the fluid is supplied to the lower surface of the substrate W, the fluid may leak due to plasma. The flow rate controller 370 may be provided in order to detect leakage of the fluid in real time. The pressure of fluid is proportional to the square of the flow rate of the fluid. If leakage of the fluid occurs, a difference occurs between the pressure value obtained by squaring the flow rate of the fluid detected by each of the flow rate controllers 372 to 378 and the pressure value detected by a corresponding one of the pressure controllers 352 to 358. Accordingly, it is possible to detect in real time whether the fluid leaks due to plasma. The flow rate controller 370 according to the embodiment of the present invention may be an orifice. However, the invention is not limited thereto.

The fluid discharge line 380 may discharge the supplied fluid. One end of the fluid discharge line 380 may be connected to a pump P, and the other end thereof may diverge into a plurality of fluid discharge lines 382 to 388. According to the present invention, the fluid discharge line 380 may include a first fluid discharge line 382, a second fluid discharge line 384, a third fluid discharge line 386, and a fourth fluid discharge line 388. The fluid discharge line 380 may be connected to the fluid supply line 340. In detail, the first fluid discharge line 382 may be connected to the first fluid supply line 342 to discharge the fluid supplied to the first fluid supply line 342 through the pump P. The second fluid discharge line 384 may be connected to the second fluid supply line 344 to discharge the fluid supplied to the second fluid supply line 344 through the pump P. The third fluid discharge line 386 may be connected to the third fluid supply line 346 to discharge the fluid supplied to the third fluid supply line 346 through the pump P. The fourth fluid discharge line 388 may be connected to the fourth fluid supply line 348 to discharge the fluid supplied to the fourth fluid supply line 348 through the pump P. According to an embodiment of the present invention, an interval between the fluid discharge lines 382 to 388 is preferably 35 mm or more, and the length from the flow rate controller 370 to an end of each of the fluid discharge lines 382 to 388 is preferably 30 mm or more. The interval between the fluid discharge lines 380 and the length thereof set in the present invention are minimum required values for ensuring smooth flow of the fluid. However, the invention is not limited thereto.

As described above, the fluid supply line 340 connected to the fluid source 320 may diverge into four fluid supply lines 342 to 348, thereby supplying the fluid to the four regions S10 to S40 of the substrate support unit 200. Each of the four branched fluid supply lines 342 to 348 may include the pressure controller 350 and the flow rate controller 370, and may be connected to a corresponding one of the branched fluid discharge lines 382 to 388 to discharge the supplied fluid. Accordingly, each of the branched fluid supply lines 342 to 348 may control flow variability of the fluid flowing therethrough as needed, thereby quickly supplying the fluid to the substrate W and quickly stabilizing the supplied fluid.

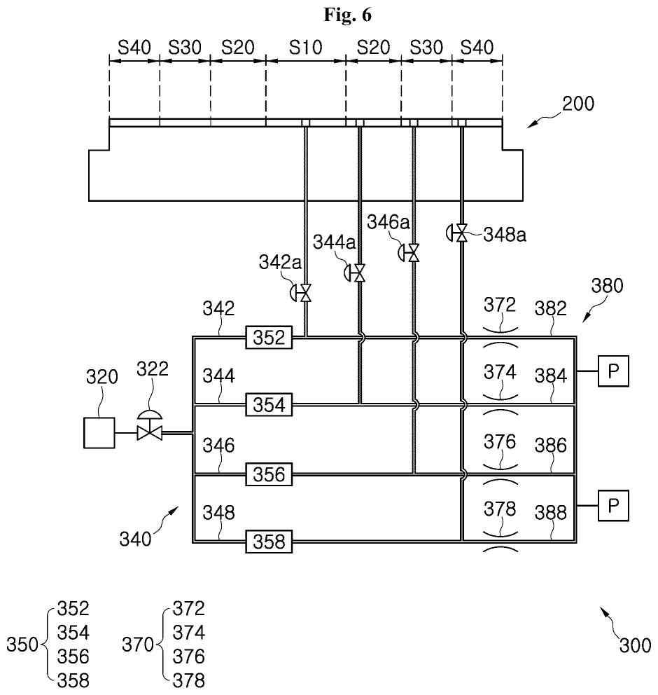

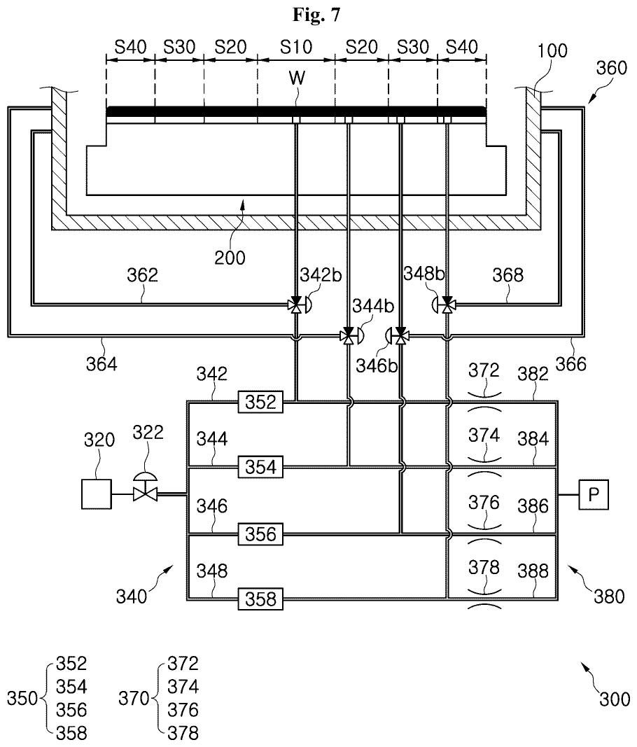

FIGS. 6 and 7 are views showing fluid supply units according to other embodiments of the present invention.

The fluid supply unit 300 shown in FIG. 6 differs from the fluid supply unit 300 shown in FIG. 5 only in the number of pumps.

Referring to FIG. 6, two pumps may be connected to the fluid discharge line 380, unlike the configuration shown in FIG. 5. In the case in which a difference between the pressures of the fluid supplied to the first to fourth fluid supply lines 342 to 348 is 20 torr or more, two pumps P may be connected to the fluid discharge line 380. If a difference between the pressures of the fluid supplied to the fluid supply lines 342 to 348 is 20 torr or more, the supplied fluid may not be smoothly discharged due to the pressure difference, and the pump P may be damaged. In order to prevent this problem, it is preferable to mount two pumps P.

The fluid supply unit 300 shown in FIG. 7 may further include a chamber fluid supply line 360.

Referring to FIG. 7, the fluid supply unit 300 may further include a chamber fluid supply line 360 configured to supply the fluid to the processing space in the chamber 100, unlike the fluid supply unit 300 shown in FIG. 5. The chamber fluid supply line 360 according to the embodiment of the present invention may include four chamber fluid supply lines 362 to 368, which branch from the passages through which the fluid is supplied to the regions S10 to S40 of the substrate support unit 200. Three-way valves 342b to 348b may be provided at points on the passages from which the chamber fluid supply lines 362 to 368 branch. The three-way valves 342b to 348b may serve not only to supply the fluid to the regions S10 to S40 of the substrate support unit 200, but also to supply the fluid to the processing space in the chamber 100 at the same time. Accordingly, in the process of dechucking the substrate W from the substrate support unit 200, charges remaining in the electrostatic chuck 220 may be removed by supplying the fluid to the substrate support unit 200, and at the same time, charges remaining on the substrate W may be reduced by supplying the fluid to the interior of the chamber 100. Through this method, it is possible to more quickly dechuck the substrate W from the substrate support unit 200.

Referring again to FIG. 3, the plasma generation unit 400 may generate plasma in the processing space in the chamber 100. Plasma may be generated in an area above the substrate support unit 200 in the chamber 100. The plasma generation unit 400 according to the embodiment of the present invention may generate plasma in the processing space in the chamber 100 using a capacitively coupled plasma (CCP) source.

However, this embodiment is not limited thereto. The plasma generation unit 400 may also generate plasma in the processing space in the chamber 100 using another type of plasma source, such as an inductively coupled plasma (ICP) source or microwaves.

The plasma generation unit 400 may include a high-frequency power supply 402 and a matching device 404. The high-frequency power supply 402 may supply high-frequency power to any one of an upper electrode and a lower electrode in order to generate a potential difference between the upper electrode and the lower electrode. Here, the upper electrode may be a shower head 410, and the lower electrode may be the substrate support unit 200. The high-frequency power supply 402 may be connected to the lower electrode, and the upper electrode may be grounded.

The shower head 410 may be provided in the chamber 100 so as to vertically oppose the electrostatic chuck 220. The shower head 410 may include a plurality of gas spray holes formed therein to evenly spray gas to the interior of the chamber 100, and may be formed to have a larger diameter than the electrostatic chuck 220. The shower head 410 may be made of a material containing a silicon component or a material containing a metal component.

The gas supply unit 500 may supply gas necessary for the process to the interior of the chamber 100. The gas supply unit 500 may include a gas source 502, a gas supply line 504, and a gas spray nozzle. The gas supply line 504 may connect the gas source 502 to the gas spray nozzle. A valve 506 may be mounted on the gas supply line 504 in order to open and close the passage of the gas supply line 504 or to regulate the flow rate of the fluid flowing through the passage.

Although one gas source 502 and one valve 506 are illustrated in FIG. 3, the invention is not limited thereto. The gas supply unit of the present invention may include a plurality of gas sources to supply a plurality of gases to the chamber 100 and a plurality of gas supply valves to independently control supply of the respective gases.

The controller 600 may comprehensively control the operation of the substrate processing apparatus 10 configured as described above. The controller 600 may be, for example, a computer, and may include a central processing unit (CPU), random access memory (RAM), read only memory (ROM), and an auxiliary storage device. The CPU may operate on the basis of a program stored in the ROM or the auxiliary storage device or a process condition to control the overall operation of the apparatus 10.

The controller 600 according to the embodiment of the present invention may perform control such that gas is supplied to the processing space in the chamber 100 in order to perform a process and the gas is converted into plasma by the plasma generation unit 400. In addition, the controller 600 may control the valves 322, 342a to 348a, and 342b to 348b, the pressure controller 350, and the flow rate controller 370 of the fluid supply unit 300 to control flow variability of the fluid supplied to the substrate support unit 200, thereby quickly stabilizing the fluid.

As is apparent from the above description, according to the present invention, flow variability of fluid supplied to a lower surface of a substrate may be controlled using a fluid supply time period and lengths and volumes of fluid supply lines.

In addition, it is possible to reduce a temperature difference between regions included in the substrate by controlling flow variability of the fluid.

The effects achievable through the present invention are not limited to the above-mentioned effects, and other effects not mentioned herein will be clearly understood by those skilled in the art from the above description.

It will be apparent to those skilled in the art that various changes in form and details may be made without departing from the essential characteristics of the invention set forth herein. Accordingly, the above detailed description is not intended to be construed to limit the invention in all aspects and to be considered by way of example. The scope of the invention should be determined by reasonable interpretation of the appended claims and all equivalent modifications made without departing from the invention should be included in the following claims.

What is claimed is:

1. A fluid control method for controlling a flow rate of fluid to be supplied to a lower surface of a substrate from a fluid supply unit comprising a fluid source configured to supply fluid and a plurality of fluid supply lines connected to the fluid source, the fluid control method comprising:
a dimension measurement step of measuring lengths and cross-sectional areas of the fluid supply lines;
a volume calculation step of calculating volumes of the fluid supply lines using the measured lengths and the measured cross-sectional areas;
a time measurement step of opening a valve provided in the fluid source to measure a time for which the fluid is supplied to the fluid supply lines; and
a control step of controlling the flow rate of the fluid based on data on the lengths and the cross-sectional areas of the fluid supply lines, the volumes of the fluid supply lines, and the time.

2. The fluid control method according to claim 1, wherein the lengths of the fluid supply lines are lengths of the fluid supply lines provided at a substrate support unit configured to support the substrate, the lengths being measured using the valve provided in the fluid source as a reference point.

3. The fluid control method according to claim 1, wherein the plurality of fluid supply lines has the same cross-sectional area.

4. The fluid control method according to claim 1, wherein the time is a time period from a time point at which the valve provided in the fluid source is opened to a time point at which the fluid is completely supplied to the fluid supply lines.

5. A fluid supply unit for supplying fluid to a lower surface of a substrate, the fluid supply unit comprising:
a fluid source configured to supply the fluid;
a fluid supply line comprising one end connected to the fluid source and configured to supply the fluid;
a pressure controller provided on the fluid supply line and configured to control pressure of the fluid;
a flow rate controller provided on the fluid supply line and configured to control a flow rate of the fluid; and
a fluid discharge line configured to discharge the supplied fluid,
wherein the fluid supply line comprises:
a first fluid supply line configured to supply a portion of fluid branched from the fluid source and introduced thereinto to a first region corresponding to a center portion of a substrate support unit configured to support the substrate;
a second fluid supply line configured to supply a portion of fluid branched from the fluid source and introduced thereinto to a second region defined around the first region;
a third fluid supply line configured to supply a portion of fluid branched from the fluid source and introduced thereinto to a third region defined around the second region; and
a fourth fluid supply line configured to supply a remaining portion of fluid branched from the fluid source and introduced thereinto to a fourth region defined around the third region.

6. The fluid supply unit according to claim 5, further comprising a valve configured to open and close a passage configured to receive the fluid introduced thereinto from the fluid source.

7. The fluid supply unit according to claim 5, wherein the pressure controller and the flow rate controller are provided on each of the first to fourth fluid supply lines.

8. The fluid supply unit according to claim 5, wherein each of the first to fourth fluid supply lines comprises a valve.

9. The fluid supply unit according to claim 8, wherein the flow rate controller is an orifice.

10. The fluid supply unit according to claim 5, wherein the fluid discharge line is connected to a pump.

11. The fluid supply unit according to claim 5, wherein each of the first to fourth fluid supply lines is connected to the fluid discharge line.

12. The fluid supply unit according to claim 5, wherein the fluid is helium.

13. A substrate processing apparatus comprising:
a chamber comprising a processing space defined therein;
a substrate support unit disposed in the processing space and configured to support a substrate;
a gas supply unit configured to supply gas to the processing space;
a plasma generation unit configured to convert the supplied gas into plasma; and
a controller configured to control the gas supply unit and the plasma generation unit,
wherein the substrate support unit comprises a fluid supply unit configured to supply fluid to a lower surface of the substrate,
wherein the fluid supply unit comprises:
a fluid source configured to supply the fluid;
a fluid supply line comprising one end connected to the fluid source and configured to supply the fluid;
a pressure controller provided on the fluid supply line and configured to control pressure of the fluid;
a flow rate controller provided on the fluid supply line and configured to control a flow rate of the fluid; and
a fluid discharge line configured to discharge the supplied fluid, and
wherein the fluid supply line comprises:
a first fluid supply line configured to supply a portion of fluid branched from the fluid source and introduced thereinto to a first region corresponding to a center portion of the substrate support unit configured to support the substrate;
a second fluid supply line configured to supply a portion of fluid branched from the fluid source and introduced thereinto to a second region defined around the first region;
a third fluid supply line configured to supply a portion of fluid branched from the fluid source and introduced thereinto to a third region defined around the second region; and
a fourth fluid supply line configured to supply a remaining portion of fluid branched from the fluid source and introduced thereinto to a fourth region defined around the third region.

14. The substrate processing apparatus according to claim 13, further comprising a valve configured to open and close a passage configured to receive the fluid introduced thereinto from the fluid source.

15. The substrate processing apparatus according to claim 13, wherein the pressure controller and the flow rate controller are provided on each of the first to fourth fluid supply lines.

16. The substrate processing apparatus according to claim 13, wherein each of the first to fourth fluid supply lines comprises a valve.

17. The substrate processing apparatus according to claim 13, wherein the fluid discharge line is connected to a pump.

18. The substrate processing apparatus according to claim 13, wherein each of the first to fourth fluid supply lines is connected to the fluid discharge line.

19. The substrate processing apparatus according to claim 13, wherein the first to fourth regions of the substrate support unit have a concentric shape.

20. The substrate processing apparatus according to claim 13, wherein the fluid is helium.
